(19) United States
(12) Patent Application Publication
(10) Pub. No.: US 2023/0034079 A1
(43) Pub. Date: Feb. 2, 2023

(54) METHOD FOR MANUFACTURING SEMICONDUCTOR STRUCTURE, SEMICONDUCTOR STRUCTURE, AND CAPACITOR STRUCTURE

(71) Applicant: CHANGXIN MEMORY TECHNOLOGIES, INC., Hefei City (CN)

(72) Inventor: Ting-Chung CHIU, Hefei City (CN)

(21) Appl. No.: 17/579,826

(22) Filed: Jan. 20, 2022

Related U.S. Application Data
(63) Continuation of application No. PCT/CN2021/109675, filed on Jul. 30, 2021.

(30) Foreign Application Priority Data
Jul. 20, 2021 (CN) 202110817629.5

(51) Int. Cl. H01L 23/532; H01L 49/02; H01L 21/768

(52) U.S. Cl. CPC H01L 23/53271; H01L 28/60; H01L 21/76883; H01L 27/10844

(57) ABSTRACT

A method for manufacturing a semiconductor structure, a semiconductor structure, and a capacitor structure are provided. The method includes: providing a substrate, a plurality of blind holes or grooves being provided in a surface of the substrate; forming filling layers in the plurality of blind holes or grooves, top surfaces of the filling layers being flush with a top surface of the substrate; and forming a cap layer on the top surfaces of the filling layers and the top surface of the substrate, in which the cap layer includes at least a film-stacked structure, the film-stacked structure includes a first cap film and a second cap film, and a doping material source of the first cap film is different from a doping material source of the second cap film.

### CROSS-REFERENCE TO RELATED APPLICATIONS

The present application is a U.S. continuation application of International Application No. PCT/CN2021/109675, filed on Jul. 30, 2021, which claims priority to Chinese Patent Application No. 202110817629.5, filed on Jul. 20, 2021. International Application No. PCT/CN2021/109675 and Chinese Patent Application No. 202110817629.5 are incorporated herein by reference in their entireties.

### TECHNICAL FIELD

This disclosure relates to, but is not limited to, a method for manufacturing a semiconductor structure, a semiconductor structure, and a capacitor structure.

### BACKGROUND

A Dynamic Random Access Memory (DRAM) is a semiconductor storage device commonly used in a computer, and is formed by numerous repetitive storage units. Each storage unit usually includes a capacitor and a transistor. A gate of the transistor is connected to a word line, a drain of the transistor is connected to a bit line, and a source of the transistor is connected to the capacitor. A voltage signal on the word line can control the transistor to be turned on or off, to read data information stored in the capacitor through the bit line or write data information into the capacitor through the bit line for storage.

At present, in a manufacturing process of a DRAM, doped polysilicon needs to be used to fill a substrate to form a capacitor. There are problems such as stress accumulation and insufficiently dense filling in a filling process, resulting in reduced performance of a DRAM.

### SUMMARY

According to a first aspect, an embodiment of this disclosure provides a method for manufacturing a semiconductor structure, including the following operations.

A substrate is provided, a plurality of blind holes or grooves being provided in a surface of the substrate.

Filling layers are formed in the plurality of blind holes or grooves, top surfaces of the filling layers being flush with a top surface of the substrate.

A cap layer is formed on the top surfaces of the filling layers and the top surface of the substrate.

The cap layer includes at least a film-stacked structure, in which the film-stacked structure includes a first cap film and a second cap film, and a doping material source of the first cap film is different from a doping material source of the second cap film.

According to a second aspect, an embodiment of this disclosure provides a semiconductor structure, including a substrate, filling layers, and a cap layer.

A plurality of blind holes or grooves are provided in a surface of the substrate.

The filling layers are located in the plurality of blind holes or grooves, and top surfaces of the filling layers are flush with a top surface of the substrate.

The cap layer is located on the top surfaces of the filling layers and the top surface of the substrate.

The cap layer includes at least a film-stacked structure, in which the film-stacked structure includes a first cap film and a second cap film, and a doping material source of the first cap film is different from a doping material source of the second cap film.

According to a third aspect, an embodiment of this disclosure provides a capacitor structure, including the semiconductor structure in the second aspect, in which a blind hole is a capacitor hole, a lower electrode, a capacitor dielectric layer, and an upper electrode are sequentially disposed from inside to outside on an inner wall of the capacitor hole, and a filling layer is located in the capacitor hole and covers the upper electrode.

### BRIEF DESCRIPTION OF THE DRAWINGS

FIG. 1 is a schematic structural diagram of a reaction chamber in the related art;

FIG. 2A is a schematic structural diagram of a substrate in the related art;

FIG. 2B is a schematic structural diagram 1 of a filling layer in the related art;

FIG. 2C is a schematic structural diagram 2 of a filling layer in the related art;

FIG. 2D is a schematic structural diagram of a cap layer in the related art;

FIG. 3 is a schematic flowchart of a method for manufacturing a semiconductor structure according to an embodiment of this disclosure;

FIG. 4A is a schematic structural diagram of a substrate according to an embodiment of this disclosure;

FIG. 4B is a schematic structural diagram 1 of a filling layer according to an embodiment of this disclosure;

FIG. 4C is a schematic structural diagram 2 of a filling layer according to an embodiment of this disclosure;

FIG. 4D is a schematic structural diagram of a cap layer according to an embodiment of this disclosure;

FIG. 5A is a detailed schematic structural diagram of a cap layer provided in the related art;

FIG. 5B is a detailed schematic structural diagram of a cap layer according to an embodiment of this disclosure;

FIG. 6 is a schematic structural diagram of a semiconductor structure according to an embodiment of this disclosure; and

FIG. 7 is a schematic structural diagram of a capacitor structure according to an embodiment of this disclosure.

### DETAILED DESCRIPTION

The technical solutions in embodiments of this disclosure will be described clearly and completely below with reference to the accompanying drawings in embodiments of this disclosure. It may be understood that the specific embodiments described herein are only used to explain this disclosure, but are not used to limit this disclosure. In addition, it needs to be noted that only parts related to this disclosure are shown in the accompanying drawings for ease of description.

Unless otherwise defined, the technical terms and scientific terms used herein have the same meanings as how they are generally understood by a person skilled in the art to which this disclosure pertains. The terms used herein are merely used for describing embodiments of this disclosure, but are not intended to limit this disclosure.

In the following description, reference is made to “some embodiments”, which describe a subset of all possible embodiments, but it may be understood that “some embodiments” may be a same subset or a different subset of all possible embodiments, and may be combined with each other without conflict.

It needs to noted that references to the terms “first, second, and third” in the embodiments of this disclosure are only to distinguish similar objects and do not denote a specific order of objects, but rather specific orders or sequences of “first, second, and third” may be interchanged, where appropriate, to enable embodiments of this disclosure described herein to be implemented in an order other than the order shown or described herein.

It should be understood that for clearer descriptions of the objectives, technical solutions, and advantages of the embodiments of this disclosure, the embodiments of this disclosure are described in detail hereinafter with reference to the accompanying drawings. However, it is understandable to those of ordinary skill in the art that many technical details are provided for a reader to better understand this disclosure in the embodiments of this disclosure. However, even in the absence of these technical details and various changes and modifications based on the following embodiments, the technical solutions claimed in this disclosure may be implemented.

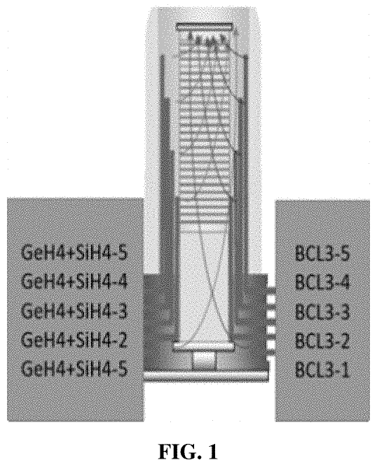

In a manufacturing process of a DRAM, doped polysilicon needs to be used to fill a substrate, to form a semiconductor structure, to further form a capacitor structure. Specifically, in an example in which a capacitor structure is filled with boron (B)/germanium (Ge)-doped polysilicon (poly, also referred to as TCP POLY), the substrate needs to be filled by a vapor deposition method, to further obtain a semiconductor structure. For vapor deposition, the substrate needs to be placed in a reaction chamber, and then raw material gases such as silane (SiH₄), boron chloride (BCl₃), and germane (GeH₄) are introduced into the reaction chamber. FIG. 1 is a schematic structural diagram of a reaction chamber in the related art. As shown in FIG. 1, the reaction chamber is a sealed chamber. A pressure and a temperature in the reaction chamber may be set as required. In addition, the reaction chamber is provided with a plurality of gas inlets that are respectively used for introducing SiH₄, BCl₃, and GeH₄.

In a related art, for a substrate including a plurality of blind holes or grooves, with the introduction of raw material gases, seed crystals of a small size are gradually formed on surfaces of the grooves. Then the seed crystals gradually grow to fill the grooves. Eventually, the grooves or blind holes are completely covered by B/Ge-doped poly. Thus, a planar plane is formed at top ends of the grooves or blind holes, to form a semiconductor structure.

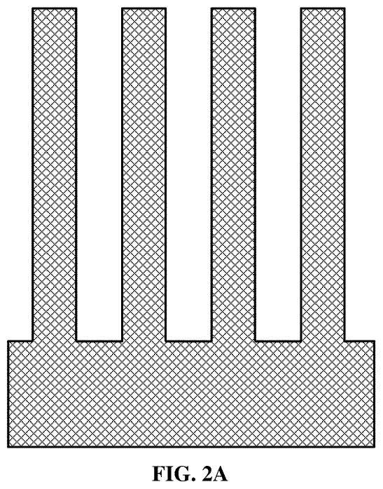

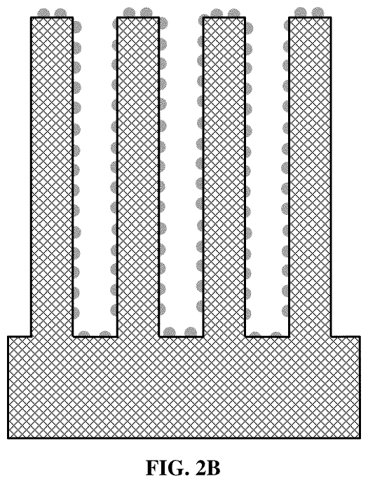

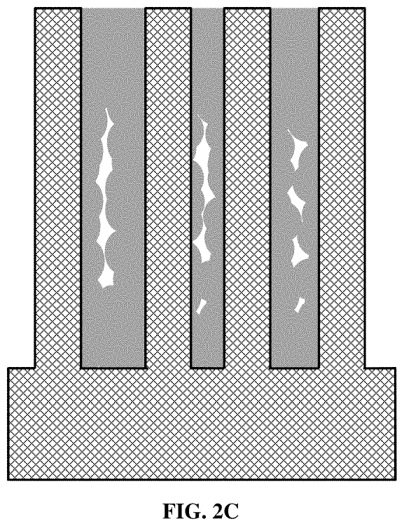

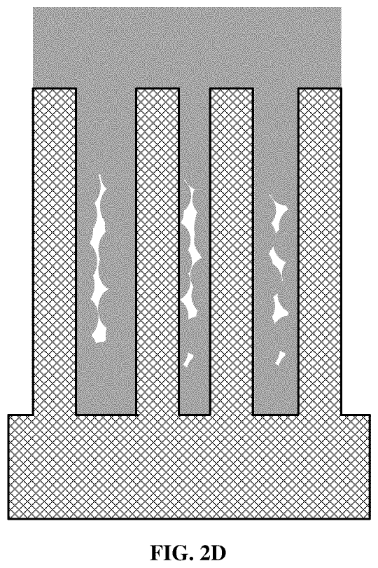

In another related art, based on the foregoing manufacturing method, a two-step method may further be used to fill: (1) Gap fill: a plurality of grooves or blind holes in a substrate are first filled with SiH₄, BCl₃, and low-speed GeH₄, until a planar plane is formed at top ends of the grooves or blind holes; (2) Cap layer formation: SiH₄, BCl₃, and high-speed GeH₄ are further deposited on the planar planes to form a cap layer. FIG. 2A is a schematic structural diagram of a substrate in the related art. FIG. 2B is a schematic structural diagram 1 of a filling layer in the related art. FIG. 2C is a schematic structural diagram 2 of a filling layer in the related art. FIG. 2D is a schematic structural diagram of a cap layer in the related art. As shown in FIG. 2A, a substrate having a plurality of grooves or blind holes is provided. As shown in FIG. 2B, vapor deposition is performed in the plurality of grooves or blind holes, to initially form seed crystals of the filling layers. As shown in FIG. 2C, the vapor deposition continues to be performed, so that the seed crystals gradually grow to form the filling layers. A top surface of the filling layer is flush with a top surface of the grooves or blind holes. As shown in FIG. 2D, the vapor deposition is further performed on the top surface of the filling layer, to form a cap layer. In this way, grains between the grooves can become smaller by adjusting the flow rate of GeH₄, to implement denser filling, and a structure resistance value can be further balanced by using low-speed GeH₄.

Exemplarily, possible reaction parameters are shown in Table 1.

TABLE 1

| | Gap Fill stage | Cap stage |
|---|---|---|
| Pressure/mtorr | 100-600 | |
| Temperature/° C. | 300-600 | |
| Flow rate of SiH₄/sccm | 300-700 | |
| Flow rate of BCl₃/sccm | 50-200 | |
| Flow rate of GeH₄/sccm | 850-1300 | 1250-1800 |
| Deposition time/min | 20-50 | 120-180 |

Note:
mtorr, the abbreviation for millitorr, a unit of atmospheric pressure;
° C., the symbol of degree Celsius, a unit of temperature;
seem, the abbreviation for standard cubic centimeter per minute, a unit of mass flow;
and min, the abbreviation for minute, a unit of time.

However, for the foregoing deposition method, in one aspect, the cap layer has a single-layer structure and is prone to cracking due to a stress accumulation in a deposition process. In another aspect, Ge in the cap layer has a relatively large grain size, and neither uniformity nor roughness is optimal. In still another aspect, a single cap layer cannot adequately balance a structure resistance value.

Based on this, embodiments of this disclosure provide a method for manufacturing a semiconductor structure. The basic concept is: providing a substrate, a plurality of blind holes or grooves being provided in a surface of the substrate; forming filling layers in the plurality of blind holes or grooves, top surfaces of the filling layers being flush with a top surface of the substrate; and forming a cap layer on the top surfaces of the filling layers and the top surface of the substrate, where the cap layer includes at least a film-stacked structure, the film-stacked structure includes a first cap film and a second cap film, and a doping material source of the first cap films is different from a doping material source of the second cap films. In this way, the film-stacked structure including the first cap film and the second cap film is used to achieve the cap layer, so that a stress accumulation problem in a deposition process can be mitigated, and the cap layer is prevented from cracking. In addition, in the film-stacked structure, a grain size can be reduced, that is, the uniformity of the cap layer is improved, and the surface roughness of the cap layer is reduced. In addition, by means of the film-stacked structure and the adjustment of a unit thickness of the film-stacked structure, a structure resistance value can be balanced, thereby eventually improving the performance of a semiconductor structure.

The embodiments of this disclosure are described below in detail with reference to the accompanying drawings.

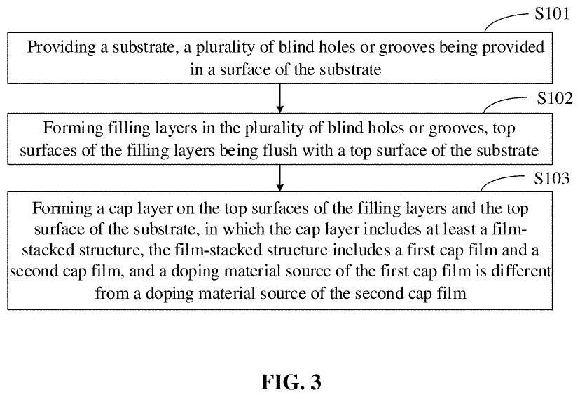

In an embodiment of this disclosure, FIG. 3 is a schematic flowchart of a method for manufacturing a semiconductor structure according to the embodiment of this disclosure. As shown in FIG. 3, the method may include the following operations.

In S101, a substrate is provided, a plurality of blind holes or grooves being provided in a surface of the substrate.

It needs to be noted that the embodiments of this disclosure provide a method for manufacturing a semiconductor structure, applicable to a capacitor.

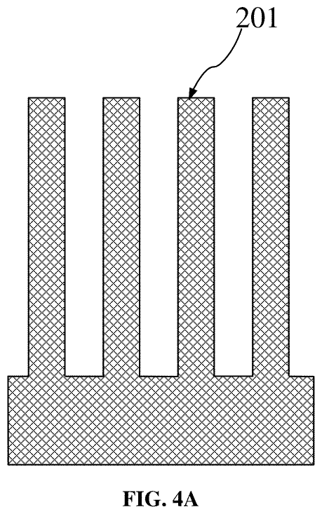

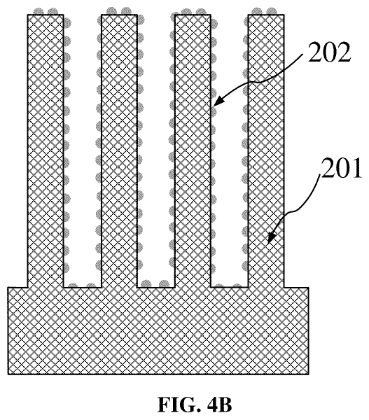

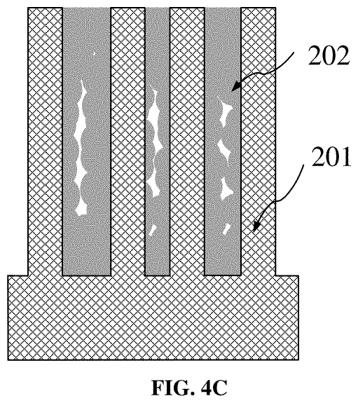

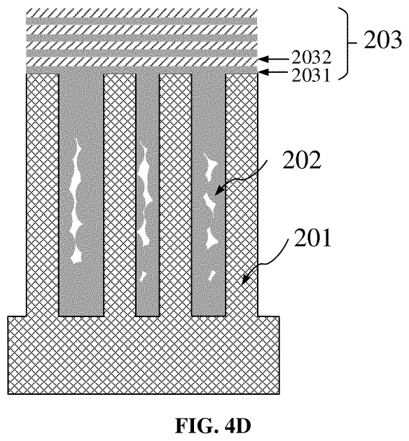

FIG. 4A is a schematic structural diagram of a substrate according to an embodiment of this disclosure. As shown in FIG. 4A, for a single-sided capacitor, there are a plurality of capacitor columns (shaded parts) on a substrate 201, and grooves are formed between the capacitor columns. For a double-sided capacitor, there are thin annular capacitors (shaded parts) on the substrate 201, and in this case, there are a plurality of blind holes at a side wall of the capacitors.

In S102, filling layers are formed in the plurality of blind holes or grooves, top surfaces of the filling layers being flush with a top surface of the substrate.

It needs to be noted that, FIG. 4B is a schematic structural diagram 1 of a filling layer according to an embodiment of this disclosure, and FIG. 4C is a schematic structural diagram 2 of a filling layer according to an embodiment of this disclosure. As shown in FIG. 4B and FIG. 4C, filling layers 202 are formed in the plurality of blind holes or grooves, until a top surface of the filling layer 202 is flush with a top surface of the substrate 201. That is, the top surface of the filling layer 202 and the top surface of the substrate 201 form a continuous planar plane.

In S103, a cap layer is formed on the top surface of the filling layer and the top surface of the substrate, where the cap layer includes at least a film-stacked structure, the film-stacked structure includes a first cap film and a second cap film, and a doping material source of the first cap film is different from a doping material source of the second cap film.

It needs to be noted that, FIG. 4D is a schematic structural diagram of a cap layer according to an embodiment of this disclosure. As shown in FIG. 4D, after the top surface of the filling layer 202 and the top surface of the substrate 201 form a planar plane, a cap layer 203 is formed on the planar plane. Here, the cap layer 203 includes at least a film-stacked structure. Each film-stacked structure includes a first cap film 2031 and a second cap film 2032. A doping material source of the first cap film 2031 is different from a doping material source of the second cap film 2032.

Here, thicknesses, forming methods, and performance parameters of the first cap film 2031 and the second cap film 2032 are not specifically limited in this embodiment of this disclosure. That is, different doping material sources are used during deposition in stack on the top surface of the filling layer 202 and the top surface of the substrate 201, to form the cap layer 203. In this way, stress accumulation in the cap layer can be reduced, thereby preventing the cap layer from fracturing.

Further, in some embodiments, the first cap film 2031 and the second cap film 2032 are formed in a same reaction chamber.

It needs to be noted that, for a semiconductor structure, the cap layer 203 may be formed by a vapor deposition method. Specifically, raw material gases are introduced into the reaction chamber in which the substrate 201 is placed, to deposit at a preset temperature and a predetermined pressure, so as to form the cap layer 203.

According to such a principle, in some embodiments, the first cap film 2031 and the second cap film 2032 are formed in a same reaction chamber. In this way, the raw material gases and environmental parameters in the reaction chamber are adjusted, so that alternate deposition can be conveniently performed on the substrate 201, to form a film-stacked structure including a first cap film 2031 and a second cap film 2032.

Further, in some embodiments, the forming a cap layer on the top surface of the filling layer and the top surface of the substrate may include the following operation.

At least a film-stacked structure is formed in stack on the top surface of the filling layer and the top surface of the substrate, until a thickness of the formed cap layer reaches a preset thickness.

It needs to be noted that, as shown in FIG. 4D, a preset thickness is determined according to an actual application requirement of a semiconductor structure 20. During the formation of the cap layer 203, film-stacked structures are sequentially formed in stack on the top surface of the filling layer 202 and the top surface of the substrate 201, until a thickness of the cap layer 203 reaches the preset thickness.

Specifically, in some embodiments, a specific formation process of the cap layer includes the following operations.

One first cap film is formed on the top surface of the filling layer and the top surface of the substrate, and one second cap film is formed on the first cap film.

The step of forming one first cap film on the second cap film and forming one second cap film on the first cap film is repeatedly performed, to form N-tier film-stacked structures, in which the N is a positive integer.

It needs to be noted that, the preset thickness may be 50 nm to 300 nm, and the N ranges from 5 to 20. That is, 5 to 20 film-stacked structures are formed in stack on the top surface of the filling layer 202 and the top surface of the substrate 201, and a thickness of the 5 to 20 film-stacked structures is 50 nm to 300 nm.

In summary, as shown in FIG. 4A to FIG. 4D, in a process of manufacturing the semiconductor structure 20, a substrate 201 having a plurality of blind holes or grooves is provided. In a first step, a filling layer 202 is formed (that is, Gap Fill), that is, the plurality of blind holes or grooves are filled. In a second step, a first cap film 2031 and a second cap film 2032 are formed repeatedly in stack on a top surface of the filling layer 202 and a top surface of the substrate 201, so as to form the cap layer 203 (that is, Cap).

Here, each of a material source of the filling layer 202 and a material source of the cap layer 203 includes a body material source and a doping material source. At present, poly is the most common capacitor filling material. In addition, to improve the performance of poly, a doping source is usually further introduced. Therefore, in some embodiments, the body material source is a silicon source, and the doping material source is a Ge source and a B source. Based on this, the silicon source and the Ge source may be used to form a first cap film 2031, and the silicon source and the B source may be used to form a second cap film 2032.

For an example in which the filling layer 202 is Ge/B-doped silicon, the first cap film 2031 is Ge-doped silicon, and the second cap film 2032 is B-doped silicon, specific process parameters of a semiconductor structure 20 are specifically given below.

First, the substrate 201 having the plurality of blind holes or grooves is placed in a reaction chamber and a Ge source, a B source, and a silicon source are separately introduced, to form the filling layer 202. In this case, the flow rate of the silicon source is 300 sccm to 700 sccm, the flow rate of the Ge source is 850 sccm to 1300 sccm, the flow rate of the B source is 50 sccm to 200 sccm, the reaction temperature is 300° C. to 600° C., and the reaction pressure is 100 mtorr to 600 mtorr.

Next, a first pressure is set in the reaction chamber, and a first temperature is set in the reaction chamber. The Ge source is introduced at a first flow rate, and the silicon source is introduced at a second flow rate, so that the first cap film 2031 is formed after a first preset period of time. Here, the first flow rate may be the same as or different from the flow rate of the silicon source during the formation of the filling layer, and the second flow rate may be the same as or different from the flow rate of the Ge source during the formation of the filling layer.

Then, a second pressure is set in the reaction chamber, and a second temperature is set in the reaction chamber. The introduction of the Ge source is stopped. The silicon source is introduced at a third flow rate, and the B source is introduced at a fourth flow rate, to form a second cap film 2032 after a second preset period of time. Here, the third flow rate may be the same as the first flow rate, or the third flow rate may be the same as the flow rate of the silicon source during the formation of the filling layer, or the third flow rate may be different from both the first flow rate and the flow rate of the silicon source during the formation of the filling layer. The fourth flow rate may be the same as or different from the flow rate of the B source during the formation of the filling layer.

Finally, a first cap film 2031 and a second cap film 2032 are repeatedly formed, until a total thickness of the cap layer reaches the preset thickness, to obtain a semiconductor structure.

Exemplarily, the first temperature ranges from 300° C. to 600° C. The first pressure ranges from 100 mtorr to 1200 mtorr. The first flow rate ranges from 300 sccm to 700 sccm. The second flow rate ranges from 1000 sccm to 1600 sccm. The first preset period of time ranges from 9 min to 24 min. The second temperature ranges from 300° C. to 600° C. The second pressure ranges from 100 mtorr to 1200 mtorr. The third flow rate ranges from 300 sccm to 700 sccm. The fourth flow rate ranges from 50 sccm to 200 sccm. The second preset period of time ranges from 3 min to 3.5 min.

It should be understood that, in the embodiments of this disclosure, each value range is a selection range of a parameter value in different manufacturing processes. For example, in a manufacturing process, during the formation of a first cap film 2031, 300° C., 100 mtorr, the flow rate of the silicon source of 300 sccm, the flow rate of the Ge source of 1000 sccm, and the deposition time of 24 min are used. During the formation of a second cap film 2032, 300° C., 100 mtorr, the flow rate of the silicon source of 300 sccm, the flow rate of the B source of 50 sccm, and the deposition time of 3.5 min are used. In another manufacturing process, during the formation of a first cap film 2031, 400° C., 500 mtorr, the flow rate of the silicon source of 500 sccm, the flow rate of the Ge source of 1300 sccm, and the deposition time of 15 min are used. During the formation of a second cap film 2032, 400° C., 500 mtorr, the flow rate of the silicon source of 500 sccm, the flow rate of the B source of 100 sccm, and the deposition time of 3.2 min are used. In still another manufacturing process, during the formation of a first cap film 2031, 600° C., 1200 mtorr, the flow rate of the silicon source of 700 sccm, the flow rate of the Ge source of 1600 sccm, and the deposition time of 9 min are used. During the formation of a second cap film 2032, 600° C., 1200 mtorr, the flow rate of the silicon source of 700 sccm, the flow rate of the B source of 200 sccm, and the deposition time of 3 min are used. In addition, different manufacturing temperatures/manufacturing pressures/gas flow rates correspond to different performance parameters, and need to be determined specifically according to actual application requirements of products.

In some other embodiments, there may be a small amount of B in a first cap film 2031, that is, a silicon source, a Ge source, and a B source are used to form the first cap film 2031, and the silicon source and the B source are used to form the second cap film 2032.

Correspondingly, the manufacturing process is adjusted as follows: first, according to process parameters of the filling layer, a substrate 301 is placed in a reaction chamber, and a Ge source, a B source, and a silicon source are introduced into the reaction chamber, until the filling layer is formed. Next, according to the process parameters of a first cap film, the Ge source, the B source, and the silicon source are still introduced into the reaction chamber, until the first cap film is formed. Then, according to process parameters of a second cap film, the introduction of the Ge source is stopped, and the B source and the silicon source are still introduced into the reaction chamber, until the second cap film is formed. In this way, a first cap film 2031 and a second cap film 2032 are repeatedly formed, until the total thickness of the cap layer reaches a preset thickness, to obtain a semiconductor structure. In this case, in the semiconductor structure, the first cap film is Ge/B poly, and the second cap film is B poly.

Further, in some embodiments, during the formation of the filling layer, the flow rate of the Ge source is less than the flow rate (that is, the second flow rate) of the Ge source during the formation of the cap layer. The benefit of this is that a grain size can be reduced by using a low flow rate of Ge, so that the filling layer can be denser, and a structure resistance value can be balanced by using a high flow rate of Ge, thereby improving the performance of a semiconductor structure.

In some embodiments, the Ge source is GeH₄, the B source is BCl₃, and the silicon source is SiH₄.

In summary, the embodiments of this disclosure relate to semiconductor memory technologies, and in particular, to the manufacturing and its procedure of a memory component, that is, the use of a transistor to control digital signal storage, which are applicable to a DRAM.

In a method for manufacturing a capacitor structure in the related art, there are problems such as stress accumulation and insufficiently dense filling in a filling process, resulting in a reduced performance of a DRAM. In the embodiments of this disclosure, during the formation of a cap layer, a Ge-doped polysilicon film (Ge poly film) and a B-doped polysilicon film (B poly film) are sequentially formed, that is, the step of capping is performed by repeatedly stacking the combination of the first cap film and the second cap film. A Ge flow and a polysilicon flow containing Ge (Ge poly flow) are used to cover the capacitor structure. When a particular thickness is reached, a B flow and a polysilicon flow containing B (B poly flow) for a second layer allow a next layer of Ge poly to begin forming a film from a small grain size from a new interface, so that the next layer of Ge poly is more uniform and denser during film formation. The repeated stacking and covering are performed on the capacitor structure by the foregoing method, thereby mitigating a stress problem/reducing a grain size of a film/balancing a resistance value.

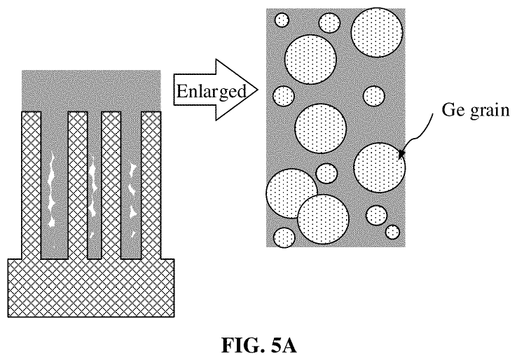

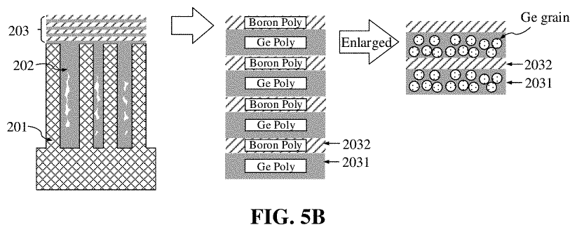

FIG. 5A is an enlarged schematic structural diagram of a cap layer provided in the related art. In the related art, the cap layer is formed by increasing a thickness of a single layer, in which there is a relatively large film stress. As shown in FIG. 5A, as can be seen from the enlarged structure of the cap layer, a Ge grain size is very large, and the uniformity/surface roughness is relatively poor. FIG. 5B is an enlarged schematic structural diagram of a cap layer according to an embodiment of this disclosure. In one aspect, as shown in FIG. 5B, as can be seen from the enlarged structure of the cap layer, by stacking a Ge poly film (that is, a first cap film) and a B poly film (that is, a second cap film) alternately, Ge grain sizes in a lower layer and an upper layer are limited, such that the stacking is more uniform and denser, thereby improving the uniformity and mitigating the roughness of the cap layer. In another aspect, by means of repeatedly stacking (B poly & Ge poly) and the adjustment of a unit thickness, a structure resistance value is balanced, and the cost of the Ge air flow can be reduced. In still another aspect, for a poly film part, by stacking, the accumulated film stress between films is reduced, and the accumulation of film stress is reduced to avoid fracturing, thereby eventually mitigating a problem that excessive large stress causes fracturing in the film.

Embodiments of this disclosure provide a method for manufacturing a semiconductor structure, in which a substrate is provided, a plurality of blind holes or grooves being provided in a surface of the substrate; filling layers are formed in the plurality of blind holes or grooves, top surfaces of the filling layers being flush with a top surface of the substrate; and a cap layer is formed on the top surfaces of the filling layers and the top surface of the substrate, where the cap layer includes at least a film-stacked structure, the film-stacked structure includes a first cap film and a second cap film, and a doping material source of the first cap film is different from a doping material source of the second cap film. In this way, a thin Ge-doped polysilicon layer (that is, a first doped layer) and a thin B-doped polysilicon layer (that is, a second doped layer) are stacked alternately, so that a Ge grain size in an upper layer is inhibited from increasing by a lower layer, such that the stacking is more uniform and denser, thereby mitigating the roughness of the cap layer. In addition, a thickness of a single layer and the quantity of stacked layers of a first cap film/a second cap film are controlled, so that a structure resistance value is balanced, and the cost can be reduced. The cap layer is formed by repeatedly stacking, so that the stress accumulation can be reduced, thereby preventing the cap layer from fracturing.

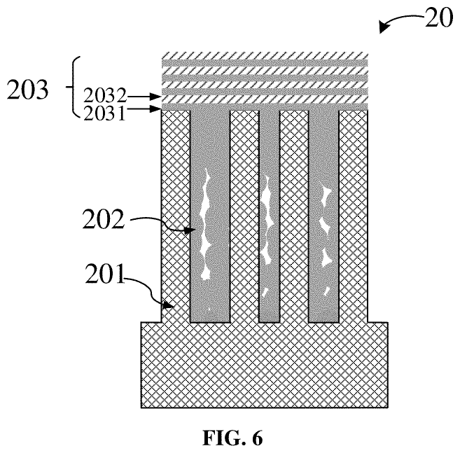

In another embodiment of this disclosure, FIG. 6 is a schematic structural diagram of a semiconductor structure 20 according to the embodiment of this disclosure. As shown in FIG. 6, the semiconductor structure 20 may include a substrate 201, filling layers 202, and a cap layer 203.

A plurality of blind holes or grooves being provided in a surface of the substrate.

The filling layers 202 are located in the plurality of blind holes or grooves, and top surfaces of the filling layers 202 are flush with a top surface of the substrate 201.

The cap layer 203 is located on the top surfaces of the filling layers 202 and the top surface of the substrate 201.

The cap layer 203 includes at least a film-stacked structure, the film-stacked structure includes a first cap film 2031 and a second cap film 2032, and a doping material source of the first cap film 2031 is different from a doping material source of the second cap film 2032.

It needs to be noted that, the embodiments of this disclosure provide a semiconductor structure 20, applicable to a capacitor. The semiconductor structure 20 includes a substrate 201, filling layers 202, and a cap layer 203. A plurality of blind holes or grooves are provided in the substrate 201. The filling layers 202 are located in the plurality of blind holes or grooves. Top surfaces of the filling layers 202 are flush with a top surface of the substrate 201. The cap layer 203 is further disposed on the filling layers 202 and the top surface of the substrate 201. Here, the cap layer 203 includes at least a film-stacked structure. The film-stacked structure includes a first cap film 2031 and a second cap film 2032. A doping material source of the first cap film 2031 is different from a doping material source of the second cap film 2032.

Further, in the cap layer 203, at least a film-stacked structure is formed in stack on the top surfaces of the filling layers 202 and the top surface of the substrate 201, until a thickness of the cap layer 203 reaches a preset thickness. Here, the preset thickness is determined according to an application scenario of the semiconductor structure 20.

Exemplarily, in the cap layer 203, a first cap film 2031 and a second cap film 2032 are alternately disposed, to form N-tier film-stacked structures, where the N is a positive integer.

In a specific embodiment, the preset thickness is 50 nm to 300 nm. The N ranges from 5 to 20. That is, the cap layer includes 5 to 20 film-stacked structures, and a total thickness of the cap layer is 50 nm to 300 nm.

Further, in some embodiments, each of a material source of the filling layer and a material source of the cap layer includes a body material source and a doping material source. The body material source includes a silicon source (for example, SiH₄). The doping material source includes a Ge source (for example, GeH₄) and a B source (for example, BCl₃). A material source of the first cap films includes a silicon source and a Ge source. A material source of the second cap films includes a silicon source and a B source.

Embodiments of this disclosure provide a semiconductor structure. The semiconductor structure includes: a substrate, a plurality of blind holes or grooves being provided in a surface of the substrate; filling layers, located in the plurality of blind holes or grooves, top surfaces of the filling layers being flush with a top surface of the substrate; and a cap layer, located on the top surfaces of the filling layers and the top surface of the substrate, where the cap layer includes at least a film-stacked structure, the film-stacked structure includes a first cap film and a second cap film, and a doping material source of the first cap film is different from a doping material source of the second cap film. In this way, the film-stacked structure including a first cap film and a second cap film is used to implement the cap layer, so that a stress accumulation problem in a deposition process can be mitigated, and thus the cap layer is prevented from cracking. In addition, in the film-stacked structure, a grain size can be reduced, that is, the uniformity of the cap layer is improved, and the surface roughness of the cap layer is reduced. In addition, by means of the film-stacked structure and the adjustment of a unit thickness of the film-stacked structure, a structure resistance value can be balanced, thereby eventually improving the performance of a semiconductor structure.

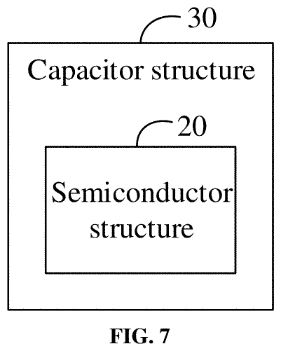

In still another embodiment, FIG. 7 shows a capacitor structure 30 according to the embodiment of this disclosure. The capacitor structure includes the semiconductor structure 20 according to any one of the foregoing embodiments. A blind hole is a capacitor hole. A lower electrode, a capacitor dielectric layer, and an upper electrode are sequentially disposed from inside to outside on an inner wall of a capacitor hole. A filling layer is located in a capacitor hole and covers an upper electrode.

For the capacitor structure 30, it includes the semiconductor structure 20, in which the film-stacked structure including a first cap film and a second cap film is used to implement the cap layer, so that a stress accumulation problem in a deposition process can be mitigated, and thus the cap layer is prevented from cracking. In addition, in the film-stacked structure, a grain size can be reduced, that is, the uniformity of the cap layer is improved, and the surface roughness of the cap layer is reduced. In addition, by means of the film-stacked structure and the adjustment of a unit thickness of the film-stacked structure, a structure resistance value can be balanced, thereby eventually improving the performance of the semiconductor structure.

In yet another embodiment, a memory is provided. The memory includes the foregoing capacitor structure 30. For the memory, it includes the capacitor structure 30, in which a film-stacked structure including a first cap film and a second cap film is used to implement the cap layer, so that a stress accumulation problem in a deposition process can be mitigated, and thus the cap layer is prevented from cracking. In addition, in the film-stacked structure, a grain size can be reduced, that is, the uniformity of the cap layer is improved, and the surface roughness of the cap layer is reduced. In addition, by means of the film-stacked structure and the adjustment of a unit thickness of the film-stacked structure, a structure resistance value can be balanced, thereby eventually improving the performance of a semiconductor structure.

Further, the memory may be a DRAM, in which the DRAM meets the DDR4/DDR5 specification.

The foregoing is merely preferred embodiments of this disclosure but is not intended to limit the scope of protection of this disclosure.

It should be noted that the terms “include”, “comprise”, or any variation thereof in this disclosure are intended to cover a non-exclusive inclusion. Therefore, a process, method, object or apparatus that includes a series of elements not only includes such elements, but also includes other elements not specified expressly, or may include inherent elements of the process, method, object or apparatus. If no more limitations are made, an element limited by “include a/an . . . ” does not exclude other same elements existing in the process, the method, the object or the apparatus which includes the element.

The foregoing sequence numbers in embodiments of this disclosure are merely for the convenience of description, and do not imply the preference among the embodiments.

The methods disclosed in several method embodiments provided in this disclosure may be arbitrarily combined with each other without causing any conflict to obtain new method embodiments.

The features disclosed in several product embodiments provided in this disclosure may be arbitrarily combined with each other without causing any conflict to obtain new product embodiments.

The features disclosed in several method or device embodiments provided in this disclosure may be arbitrarily combined with each other without causing any conflict to obtain new method or device embodiments.

The above are merely specific implementation modes of this disclosure, but are not intended to limit the protection scope of this disclosure. Any variation or replacement that may be readily figured out by a person skilled in the art within the technical scope disclosed in this disclosure shall fall within the protection scope of this disclosure. Therefore, the protection scope of this disclosure shall be subject to the protection scope of the claims.

### INDUSTRIAL APPLICABILITY

In the embodiments of this disclosure, the manufacturing method includes: providing a substrate, a plurality of blind holes or grooves being provided in a surface of the substrate; forming filling layers in the plurality of blind holes or grooves, a top surface of the filling layer being flush with a top surface of the substrate; and forming a cap layer on the top surface of the filling layer and the top surface of the substrate, where the cap layer includes at least a film-stacked structure, the film-stacked structure includes a first cap film and a second cap film, and a doping material source of a first cap film is different from a doping material source of a second cap film. In this way, the film-stacked structure including a first cap film and a second cap film is used to implement the cap layer, so that a stress accumulation problem in a deposition process can be prevented, the uniformity of the cap layer is improved and the surface roughness of the cap layer is mitigated, and a structure resistance value can be also balanced, thereby improving the performance of a semiconductor structure.

1. A method for manufacturing a semiconductor structure, comprising:
providing a substrate, a plurality of blind holes or grooves being provided in a surface of the substrate;
forming filling layers in the plurality of blind holes or grooves, top surfaces of the filling layers being flush with a top surface of the substrate; and
forming a cap layer on the top surfaces of the filling layers and the top surface of the substrate,
wherein the cap layer comprises at least a film-stacked structure, the film-stacked structure comprises a first cap film and a second cap film, and a doping material source of the first cap film is different from a doping material source of the second cap film.

2. The method according to claim 1, wherein the first cap film and the second cap film are formed in a same reaction chamber.

3. The method according to claim 1, wherein the forming a cap layer on the top surfaces of the filling layers and the top surface of the substrate comprises:
forming the at least a film-stacked structure in stack on the top surfaces of the filling layers and the top surface of the substrate, until a thickness of the cap layer formed reaches a preset thickness.

4. The method according to claim 3, wherein the forming the film-stacked structure on the top surfaces of the filling layers and the top surface of the substrate comprises:
forming one first cap film on the top surfaces of the filling layers and the top surface of the substrate, and forming one second cap film on the first cap film; and
repeatedly performing a step of forming one first cap film on the second cap film and forming one second cap film on the first cap film, to form N-tier film-stacked structures, wherein the N is a positive integer.

5. The method according to claim 4, wherein the preset thickness is 50 nm to 300 nm, and the N ranges from 5 to 20.

6. The method according to claim 4, wherein each of a material source of the filling layers and a material source of the cap layer comprises a body material source and a doping material source.

7. The method according to claim 6, wherein the body material source comprises a silicon source, and the doping material source comprises a germanium source and a boron source; and
a material source of the first cap film comprises the silicon source and the germanium source, and a material source of the second cap film comprises the silicon source and the boron source.

8. The method according to claim 7, wherein the forming the first cap film comprises:
setting a first pressure and a first temperature in a reaction chamber in which the substrate is placed; and
introducing the silicon source into the reaction chamber at a first flow rate, and the germanium source into the reaction chamber at a second flow rate for a first preset period of time, to form the first cap film.

9. The method according to claim 8, wherein the first temperature ranges from 300° C. to 600° C., the first pressure ranges from 100 mtorr to 1200 mtorr, the first flow rate ranges from 300 sccm to 700 sccm, the second flow rate ranges from 1000 sccm to 1600 sccm, and the first preset period of time ranges from 9 min to 24 min.

10. The method according to claim 8, wherein the forming the second cap film comprises:
setting a second pressure and a second temperature in the reaction chamber; and
introducing the silicon source into the reaction chamber at a third flow rate, and the boron source into the reaction chamber at a fourth flow rate for a second preset period of time, to form the second cap film.

11. The method according to claim 10, wherein the second temperature ranges from 300° C. to 600° C., the second pressure ranges from 100 mtorr to 1200 mtorr, the third flow rate ranges from 300 sccm to 700 sccm, the fourth flow rate ranges from 50 sccm to 200 sccm, and the second preset period of time ranges from 3 min to 3.5 min.

12. The method according to claim 7, wherein a flow rate of the germanium source during formation of the filling layers is less than a flow rate of the germanium source during formation of the cap layer.

13. The method according to claim 7, wherein the germanium source is germane (GeH₄), the boron source is boron chloride (BCl₃), and the silicon source is silane (SiH₄).

14. A semiconductor structure, comprising:
a substrate, a plurality of blind holes or grooves being provided in a surface of the substrate;
filling layers, located in the plurality of blind holes or grooves, top surfaces of the filling layers being flush with a top surface of the substrate; and
a cap layer, located on the top surfaces of the filling layers and the top surface of the substrate,
wherein the cap layer comprises at least a film-stacked structure, the film-stacked structure comprises a first cap film and a second cap film, and a doping material source of the first cap film is different from a doping material source of the second cap film.

15. The semiconductor structure according to claim 14, wherein in the cap layer, the at least a film-stacked structure is formed in stack on the top surfaces of the filling layers and the top surface of the substrate, until a thickness of the cap layer reaches a preset thickness.

16. The semiconductor structure according to claim 15, wherein in the cap layer, the first cap film and the second cap film are alternately disposed, to form N-tier film-stacked structures, wherein the N is a positive integer.

17. The semiconductor structure according to claim 16, wherein the preset thickness is 50 nm to 300 nm, and the N ranges from 5 to 20.

18. The semiconductor structure according to claim 14, wherein each of a material source of the filling layers and a material source of the cap layer comprises a body material source and a doping material source.

19. The semiconductor structure according to claim 18, wherein the body material source comprises a silicon source, and the doping material source comprises a germanium source and a boron source; and
a material source of the first cap film comprises the silicon source and the germanium source, and a material source of the second cap film comprises the silicon source and the boron source.

20. A capacitor structure, comprising the semiconductor structure according to claim 14, wherein a blind hole is a capacitor hole, wherein a lower electrode, a capacitor dielectric layer, and an upper electrode are sequentially disposed from inside to outside on an inner wall of the capacitor hole, and a filling layer is located in the capacitor hole and covers the upper electrode.
